(19) United States
(12) Patent Application Publication
(10) Pub. No.: US 2023/0290848 A1
(43) Pub. Date: Sep. 14, 2023

(54) SEMICONDUCTOR DEVICE AND METHOD FOR FABRICATING THE SAME

(71) Applicant: SK hynix Inc., Gyeonggi-do (KR)

(72) Inventors: Dong Soo KIM, Gyeonggi-do (KR); Se Han KWON, Gyeonggi-do (KR)

(21) Appl. No.: 17/979,941

(22) Filed: Nov. 3, 2022

(30) Foreign Application Priority Data
Mar. 10, 2022 (KR) 10-2022-0030017

(51) Int. Cl. H01L 29/423; H01L 21/768; H01L 29/51; H01L 29/66

(52) U.S. Cl. CPC H01L 29/4236; H01L 21/76841; H01L 29/517; H01L 29/6653; H01L 21/76829

(57) ABSTRACT

A semiconductor device includes: a substrate including a gate trench; a gate dielectric layer formed along sidewalls and bottom surfaces of the gate trench; a high work function layer and a lower gate electrode that fill a bottom portion of the gate trench over the gate dielectric layer; an upper gate electrode including a low work function adjusting element over the lower gate electrode and including the same metal nitride as a material of the lower gate electrode; and a capping layer that gap-fills the other portion of the gate trench over the upper gate electrode.

### CROSS-REFERENCE TO RELATED APPLICATIONS

The present application claims priority of Korean Patent Application No. 10-2022-0030017, filed on Mar. 10, 2022, which is incorporated herein by reference in its entirety.

### BACKGROUND

### 1. Field

Various embodiments of the present invention relate to a semiconductor device and a method for fabricating the same, and more particularly, to a semiconductor device including a buried gate and a method for fabricating the semiconductor device.

### 2. Description of the Related Art

Demand for higher integration of semiconductor devices is increasing. However, this causes diverse problems which need to be addressed, such as, for example, a decrease in a process margin of an exposure process for defining fine patterns, making it increasingly difficult to realize a semiconductor device. Also, with the development of the electronic industry, the demand for high-speed semiconductor devices is also increasing. Various studies and proposals have been conducted to fulfill the demands for high integration and/or high speed of the semiconductor devices, however, further improvements are needed.

### SUMMARY

Embodiments of the present invention are directed to a semiconductor device with improved electrical characteristics and a method for fabricating the same

In accordance with an embodiment of the present invention, a semiconductor device includes: a substrate including a gate trench; a gate dielectric layer formed along sidewalls and bottom surfaces of the gate trench; a high work function layer and a lower gate electrode that fill a bottom portion of the gate trench over the gate dielectric layer; an upper gate electrode including a low work function adjusting element over the lower gate electrode and including the same metal nitride as a material of the lower gate electrode; and a capping layer that gap-fills the other portion of the gate trench over the upper gate electrode.

In accordance with another embodiment of the present invention, a semiconductor device includes: a substrate including a gate trench; a gate dielectric layer formed along sidewalls and a bottom surface of the gate trench; a high work function layer and a lower gate electrode that fill a bottom portion of the gate trench over the gate dielectric layer; a low work function layer and an upper gate electrode that fill a portion of the gate trench over the lower gate electrode; and a capping layer that gap-fills the other portion of the gate trench over the upper gate electrode and a low work function inducing layer.

In accordance with yet another embodiment of the present invention, a method for fabricating a semiconductor device includes: forming a gate trench in a substrate; forming a gate dielectric layer along sidewalk and a bottom surface of the gate trench; forming a high work function layer and a lower gate electrode that fill a bottom portion of the gate trench over the gate dielectric layer; forming an upper gate electrode including a low work function adjusting element over the lower gate electrode and including the same metal material as a material of the lower gate electrode; and forming a capping layer gap-filling the other portion of the gate trench over the upper gate electrode.

In accordance with still another embodiment of the present invention, a method for fabricating a semiconductor device includes: forming a gate trench in a substrate; forming a gate dielectric layer along sidewalk and a bottom surface of the gate trench; forming a high work function layer and a lower gate electrode that fill a bottom portion of the gate trench over the gate dielectric layer; forming a low work function layer and an upper gate electrode that fill a portion of the gate trench over the lower gate electrode; and forming a capping layer that gap-fills the other portion of the gate trench over the upper gate electrode.

### BRIEF DESCRIPTION OF THE DRAWINGS

FIG. 1 is a plan view illustrating a semiconductor device in accordance with an embodiment of the present invention.

FIG. 2A is a cross-sectional view taken along a line A-A′ of FIG. 1 in accordance with a first embodiment of the present invention.

FIG. 2B is a cross-sectional view taken along a line B-B′ of FIG. 1 in accordance with the first embodiment of the present invention.

FIGS. 3A to 3F are cross-section& views illustrating a method for fabricating the semiconductor device in accordance with the first embodiment of the present invention.

FIGS. 4A to 4D are cross-sectional views illustrating a method for fabricating the semiconductor device in accordance with the first embodiment of the present invention.

FIG. 5 is a cross-sectional view illustrating a semiconductor device in accordance with a second embodiment of the present invention.

FIGS. 6A to 6E are cross-sectional views illustrating a method for fabricating the semiconductor device in accordance with the second embodiment of the present invention.

FIG. 7 is a cross-sectional view illustrating a semiconductor device in accordance with a third embodiment of the present invention.

FIGS. 8A to 8C are cross-sectional views illustrating an example of a method for fabricating the semiconductor device in accordance with the third second embodiment of the present invention.

FIG. 9 is a cross-sectional view illustrating a semiconductor device in accordance with a fourth embodiment of the present invention embodiment.

### DETAILED DESCRIPTION

Embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

Hereinafter, in the following embodiments of the present invention, a threshold voltage Vt may depend on a flat band voltage (VFB). The flat band voltage VFB may depend on a work function. The work function may be engineered by diverse methods. For example, the work function may be controlled by a material of a gate electrode, a material between the gate electrode and a channel, and the like. By increasing or decreasing the work function, the flat band voltage may be shifted. The high work function may shift the flat band voltage in a positive direction, and the low work function may shift the flat band voltage in a negative direction. As described above, the threshold voltage Vt may be modulated by shifting the flat band voltage. According to embodiments of the present invention, the threshold voltage Vt may be modulated by shifting the flat band voltage even though the channel concentration is reduced or channel doping is omitted. In particular, the flat band voltage may be lowered by a low work function material or a dipole, thereby improving the gate induced drain leakage (GIRL).

Hereinafter, according to embodiments of the present invention, a buried gate structure may be positioned in a gate trench. The buried gate structure may include a gate electrode filling the gate trench, and, therefore, the gate electrode is also referred to as a ‘buried gate electrode’. The gate electrode may include a lower gate electrode and an upper gate electrode. The lower gate electrode may fill a lower portion of the gate trench, and the upper gate electrode may fill an upper portion of the gate trench over the lower gate electrode. As described above, the gate electrode may be a dual gate electrode in which the upper gate electrode is positioned over the lower gate electrode. The lower gate electrode may overlap with a channel. The upper gate electrode may overlap with first and second source/drain regions (i.e., source/drain regions).

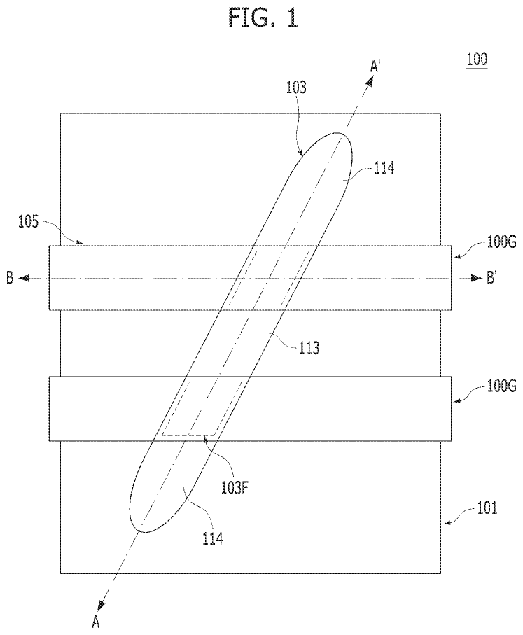

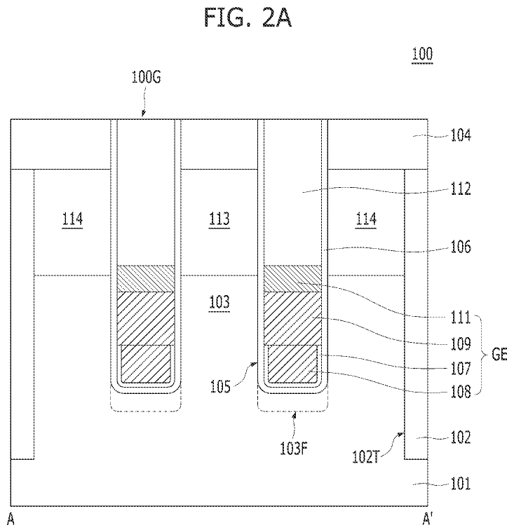

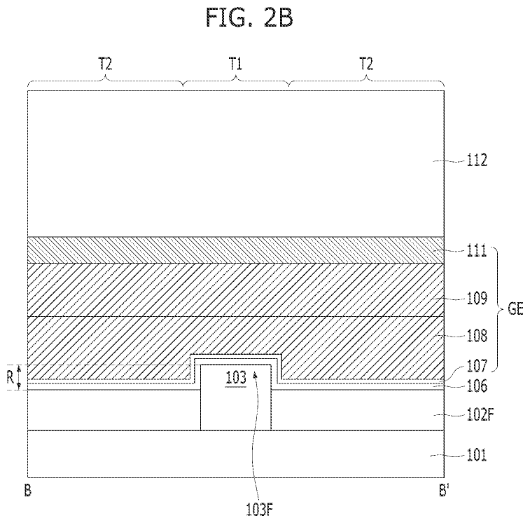

FIG. 1 is a plan view illustrating a semiconductor device in accordance with an embodiment of the present invention. FIG. 2A is a cross-sectional view taken along a line A-A′ of the semiconductor device shown in FIG. 1 in accordance with a first embodiment of the present invention. FIG. 2B is a cross-sectional view taken along a line B-B′ of the semiconductor device shown in FIG. 1 in accordance with the first embodiment of the present invention.

Referring to FIGS. 1, 2A and 2B, the semiconductor device 100 may include a buried gate structure 100G, and first and second source/drain regions 113 and 114. An isolation layer 102 and an active region 103 may be formed in the substrate 101. A first source/drain region 113 and a second source/drain region 114 may be formed in the active region 103, A trench crossing the active region 103 and the isolation layer 102, that is, a gate trench 105, may be formed. A buried gate structure 100G may be formed in the gate trench 105. A channel may be formed between the first source/drain region 113 and the second source/drain region 114 by the buried gate structure 100G, A channel may be defined along a profile of the gate trench 105. The semiconductor device 100 may be a portion of a memory cell. For example, the semiconductor device 100 may be a cell transistor of a Dynamic Random Access Memory (DRAM).

The semiconductor device 100 may be formed in the substrate 101. The substrate 101 may be a material suitable for semiconductor processing. The substrate 101 may include a semiconductor substrate. The substrate 101 may be formed of a material containing silicon. The substrate 101 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The substrate 101 may include other semiconductor materials such as germanium. The substrate 101 may include a III/V-group semiconductor substrate, for example, a compound semiconductor substrate such as GaAs. The substrate 101 may include a Silicon-On-Insulator (SOI) substrate.

The isolation layer 102 and the active region 103 may be formed in the substrate 101. The active region 103 may be defined by the isolation layer 102. The isolation layer 102 may be a shallow trench isolation region (STI) which is formed by trench etching. The isolation layer 102 may be formed by filling the shallow trench, for example, isolation trench 102T, with a dielectric material. The isolation layer 102 may include silicon oxide, silicon nitride, or a combination thereof.

The gate trench 105 may be formed in the substrate 101. From the perspective of FIG. 1, the gate trench 105 may have a line shape extending in one direction. The gate trench 105 may have a line shape crossing the active region 103 and the isolation layer 102, The gate trench 105 may have a shallower depth than the isolation trench 102T, According to another embodiment of the present invention, the bottom portion of the gate trench 105 may have a curvature.

A first source drain region 113 and a second source/drain region 114 may be formed in the active region 103, The first source/drain region 113 and the second source/drain region 114 may be regions doped with a conductive dopant. For example, the conductive dopant may be phosphorus (P), arsenic (As), antimony (Sb), or boron (B). The first source/drain region 113 and the second source/drain region 114 may be doped with a dopant of the same conductivity type. The first source/drain region 113 and the second source/drain region 114 may be positioned in the active region 103 on both sides of the gate trench 105. The bottom surfaces of the first source/drain region 113 and the second source/drain region 114 may be positioned at a predetermined depth from the top surface of the active region 103, The first source/drain region 113 and the second source/drain region 114 may contact a sidewall of the gate trench 105, The bottom surfaces of the first source/drain region 113 and the second source/drain region 114 may be higher than the bottom surface of the gate trench 105.

The gate trench 105 may include a first trench T1 and a second trench T2. The first trench T1 may be formed in the active region 103. The second trench T2 may be formed in the isolation layer 102. The gate trench 105 may continuously extend from the first trench T1 toward the second trench T2. In the gate trench 105, the first trench T1 and the second trench T2 may have their bottom surfaces positioned at different levels. For example, the bottom surface of the first trench T1 may be positioned at a higher level than the bottom surface of the second trench T2. The height difference between the first trench T1 and the second trench T2 may be formed as the isolation layer 102 is recessed. Accordingly, the second trench T2 may include a recess region R having a lower bottom surface than the bottom surface of the first trench T1. A fin 103F may be formed in the active region 103 due to the height difference between the first trench T1 and the second trench T2. As a result, the active region 103 may include the fin 103F.

In this way, the fin 103F may be formed below the first trench T1, and the sidewall of the fin 103F may be exposed by the recessed isolation layer 102F. The fin 103F may be a portion where a channel is formed. The fin 103F is also referred to as a saddle fin. The fin region 103F may increase the channel width and improve electrical characteristics.

According to another embodiment of the present invention, the fin 103F may be omitted.

A buried gate structure 100G may be embedded in the gate trench 105. The buried gate structure 100G may be positioned in the active region 103 between the first source/drain region 113 and the second source/drain region 114 and extend into the isolation layer 102, In the buried gate structure 100G, the bottom surface of a portion positioned in the active region 103 and the bottom surface of a portion positioned in the isolation layer 102 may be positioned at different levels. When the fin 103F is omitted, in the buried gate structure 100G, the bottom surface of the portion positioned in the active region 103 and the bottom surface of the portion positioned in the isolation layer 102 may be positioned at the same level.

The buried gate structure 100G may include a gate dielectric layer 106, a gate electrode structure GE, and a capping layer 112.

The gate dielectric layer 106 may be conformally formed on the bottom surface and sidewalls of the gate trench 105. The gate dielectric layer 106 may include silicon oxide, silicon nitride, silicon oxynitride, a high-k material, or a combination thereof. The high-k material may include a material having a higher dielectric constant than that of silicon oxide. For example, the high-k material may include a material having a dielectric constant of approximately 3.9 or more. To take another example, the high-k material may include a material having a dielectric constant of approximately 10 or more. To take yet another example, the high-k material may include a material having a dielectric constant of approximately 10 to 30. The high-k material may include at least one metallic element. The high-k material may include a hafnium-containing material. The hafnium-containing material may include hafnium oxide, hafnium silicon oxide, hafnium silicon oxynitride, or a combination thereof. According to another embodiment of the present invention, the high-k material may include lanthanum oxide, lanthanum aluminum oxide, zirconium oxide, zirconium silicon oxide, zirconium silicon oxynitride, aluminum oxide, or a combination thereof. As the high-k material, other known high-k materials may be selectively used. The gate dielectric layer 106 may include a metal oxide.

The top surface of the gate electrode structure GE may be positioned at a lower level than the top surface of the active region 103. The gate electrode structure GE may include a stacked structure including a high work function layer 107, a first gate electrode 108, a second gate electrode 109, and a third gate electrode 111.

The high work function layer 107 may have a relatively high work function, High work function as this term is used herein means a work function which is higher than the mid-gap work function of silicon. Low work function means a lower work function than the mid-gap work function of silicon. For example, the high work function may have a work function which is higher than approximately 4.5 eV, and the low work function may have a work function lower than approximately 4.5 eV.

The high work function layer 107 may include at least one of a metal oxide and a metal nitride. For example, the high work function layer 107 may include at least one of titanium oxide (TiO₂), aluminum oxide (Al₂O₃), and titanium aluminum nitride (TiAlN). A threshold voltage Vt may be modulated by the high work function layer 107. For example, the threshold voltage Vt may be shifted by the high work function layer 107.

The first and second gate electrodes 108 and 109 may include the same material. The first and second gate electrodes 108 and 109 may include a metal nitride, for example, titanium nitride (TiN).

The third gate electrode 111 may include the same metal nitride as that of the first and second gate electrodes 108 and 109, Hence, the third gate electrode 111 may form a continuous layer with the second gate electrode 109. However, the third gate electrode 111 may be doped/diffused with a low work function adjusting element. So, the third gate electrode 111 may be formed by doping/diffusing a low work function adjusting element inside only a top portion of the metal nitride of the second gate electrode 109. Because of the doping, the third gate electrode 111 may have a lower work function than the work functions of the first and second gate electrodes 108 and 109. For example, the low work function adjusting element may be phosphorus (P) or lanthanum (La), For example, the third gate electrode 110 may include titanium nitride which is doped/diffused with phosphorus (P) (P-doped/diffused TiN) or titanium nitride which is doped/diffused with lanthanum (La) (La-doped/diffused TiN).

The stack of the first and second gate electrodes 108 and 109 is also referred to as a ‘lower gate electrode’. The third gate electrode 111 is also referred to as an ‘upper gate electrode’. The lower gate electrode and the upper gate electrode may have different work functions. The upper gate electrode may have a lower work function than that of the lower gate electrode. The top surface of the lower gate electrode may be positioned at a level lower than the bottom surfaces of the first and second source/drain regions 113 and 114. The lower gate electrode may not horizontally overlap with the first and second source/drain regions 113 and 114. The bottom surface of the upper gate electrode 111 may be positioned at a lower level than the bottom surfaces of the first and second source/drain regions 113 and 114. The upper gate electrode 111 may horizontally overlap with the first and second source/drain regions 113 and 114.

The thickness of the third gate electrode 111 may be thinner than the thickness of the second gate electrode 109, however, the spirit and concept of the present embodiment are not limited thereto. The thicknesses of the second and third gate electrodes 109 and 111 are measured in the stacking direction of the gate electrode structure GE.

According to another embodiment of the present invention, the thickness of the third gate electrode 111 may be the same as the thickness of the second gate electrode 109 or may be greater than the thickness of the second gate electrode 109.

According to another embodiment of the present invention, the second gate electrode 109 may be omitted. In other words, all the second gate electrodes 109 may be replaced with the third gate electrodes 111 by the low work function adjusting element. Accordingly, the third gate electrode 111 may directly contact the first gate electrode 108. In this case, the thickness of the first gate electrode 108 may be adjusted to be the same as the thickness of the third gate electrode 111.

The capping layer 112 may be formed over the gate electrode structure GE for protecting the gate electrode structure GE. In the illustrated embodiment of FIG. 2A, the capping layer 112 is formed on top of the third gate electrode 111 and protects the third gate electrode 111. The capping layer 112 may include a dielectric material. The capping layer 112 may, for example, include silicon nitride, silicon oxynitride, or a combination thereof. According to an embodiment, the capping layer 112 may include a combination of silicon nitride and silicon oxide. The capping layer 112 may include a silicon nitride liner and a spin-on-dielectric (SOD) material.

According to an embodiment of the present invention, the volume of the gate electrode including a metal may be increased by forming the first to third gate electrodes 108, 109, and 111 of a same metal material. As a result, the resistance Rs of the device may be Improved by reducing the specific resistance of the gate electrode.

According to an embodiment of the present invention, a channel dose may be reduced by forming the high work function layer 107 between the first gate electrode 108 and the gate dielectric layer 106 to modulate the threshold voltage Vt. Also, it is possible to improve the gate induced drain leakage (GIDL) by doping the third gate electrode 111 horizontally overlapping with the first and second source/drain regions 113 and 114 with a low work function adjusting element.

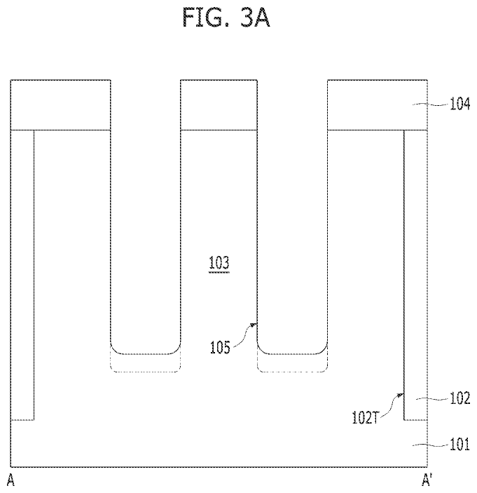

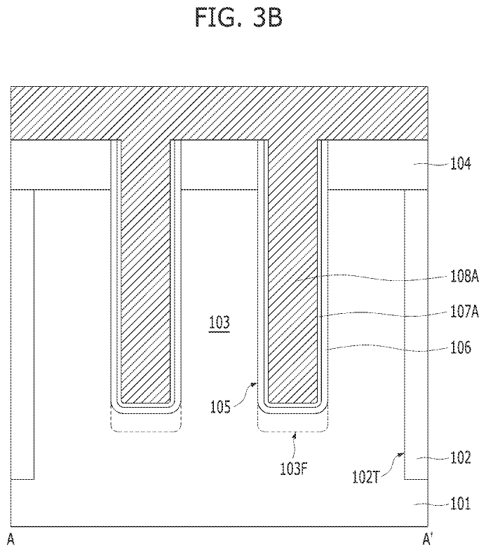

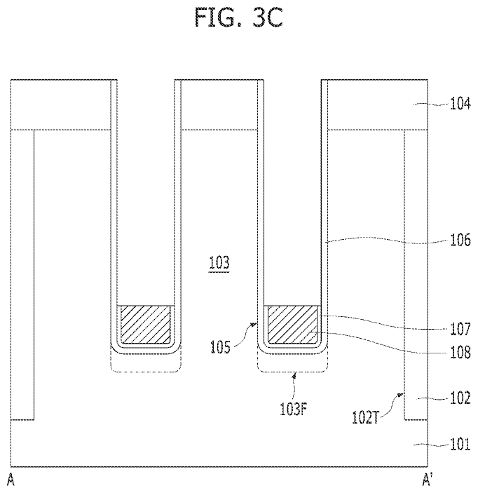

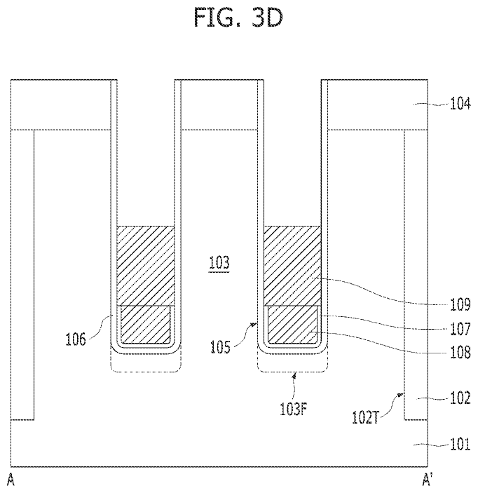

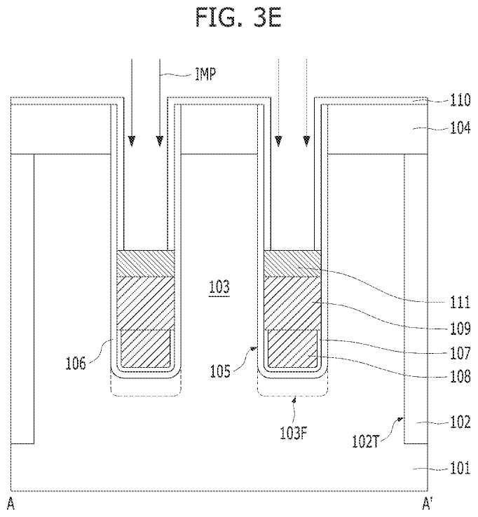

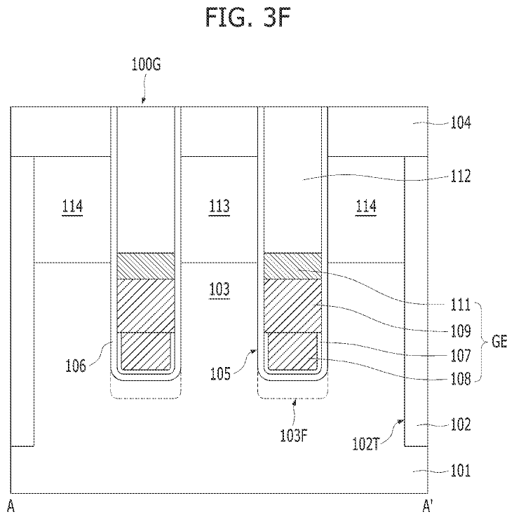

FIGS. 3A to 3F are cross-sectional views illustrating a method for fabricating the semiconductor device in accordance with the first embodiment of the present invention.

Referring to FIG. 3A, an isolation layer 102 may be formed over a substrate 101 to define an active region 103, The isolation layer 102 may be formed by a Shallow Trench Isolation (STI) process. For example, an isolation trench 102T may be formed by etching the substrate 101. The isolation trench 102T may be filled with a dielectric material to form the isolation layer 102. The isolation layer 102 may include silicon oxide, silicon nitride, or a combination thereof. A chemical vapor deposition (CVD) or other deposition processes may be used to fill the isolation trench 1021 with a dielectric material, A planarization process such as chemical-mechanical polishing (CMP) may additionally be used for removing any excess dielectric material.

A gate trench 105 may be formed in the substrate 101. The gate trench 105 may be formed in a shape of a line crossing the active region 103 and the isolation layer 102. The gate trench 105 may be formed by an etching process using the hard mask 104 as an etching mask. The hard mask 104 may be formed over the substrate 101 and it may have at least one line-shaped opening. The hard mask 104 may be formed of a material having an etch selectivity with respect to the substrate 101. For example, the hard mask 104 may be formed of silicon oxide such as Tetra Ethyl Ortho Silicate (TEOS). The gate trench 105 may be shallower than the isolation trench 102T. The gate trench 105 may have a depth sufficient to increase the average cross-sectional area of the gate electrode which is formed subsequently inside the gate trench 105. Accordingly, the resistance of the gate electrode may be reduced.

According to an embodiment of the present invention, the bottom portion of the gate trench 105 may have a curvature.

Subsequently, the fin 103F may be formed. The fin 103F may be formed by recessing the isolation layer 102 below the gate trench 105, The fin 103F was described earlier in reference with FIG. 2B.

Referring to FIG. 3B, a gate dielectric layer 106 may be formed on the surfaces of the gate trench 105 and the hard mask 104. Before the gate dielectric layer 106 is formed, etch damage on the surface of the gate trench 105 may be cured. For example, after a sacrificial oxide Is formed by a thermal oxidation process, the sacrificial oxide may be removed.

The gate dielectric layer 106 may be formed by a thermal oxidation process. According to another embodiment of the present invention, the gate dielectric layer 106 may be formed by a Chemical Vapor Deposition (CVD) process or an Atomic Layer Deposition (ALD) process. The gate dielectric layer 106 may include a high-k material, an oxide, a nitride, an oxynitride, or a combination thereof. The high-k material may include a hafnium-containing material. The hafnium-containing material may include hafnium oxide, hafnium silicon oxide, hafnium silicon oxynitride, or a combination thereof. According to another embodiment of the present invention, the high-k material may include lanthanum oxide, lanthanum aluminum oxide, zirconium oxide, zirconium silicon oxide, zirconium silicon oxynitride, aluminum oxide, or combinations thereof. As for the high-k material, other known high-k materials may optionally be used. The gate dielectric layer 106 may be or include a material having a high oxygen atomic areal density.

A work function adjusting layer 107A may be formed over the gate dielectric layer 106, The work function adjusting layer 107A may be conformally formed on the surface of the gate dielectric layer 106. The work function adjusting layer 107A may be or include a material having a high work function. The work function adjusting layer 107A may include a metal-based material. The work function adjusting layer 107A may include at least one of a metal oxide or a metal nitride. For example, the work function adjusting layer 107A may include at least one of titanium oxide (TiO₂), aluminum oxide (Al₂O₃), and titanium aluminum nitride (TiAlN). In this case, the titanium oxide (TiO₂) may be formed by first forming a titanium layer conformally over the gate dielectric layer 106 and, then, reacting the titanium layer with a portion of the gate dielectric layer 106 through a heat treatment.

A first gate electrode layer 108A may be formed over the work function adjusting layer 107A, The first gate electrode layer 108A may fill the gate trench 105, The first gate electrode layer 108A may include a metal nitride. For example, the first gate electrode layer 108A may include titanium nitride (TiN).

Referring to FIG. 3C, a high work function layer 107 and a first gate electrode 108 filling the bottom portion of the gate trench 105 may be formed. The top surfaces of the high work function layer 107 and the first gate electrode 108 may be positioned at the same level, To form the high work function layer 107 and the first gate electrode 108, a recessing process may be performed. The recessing process may include dry etching, such as, for example, an etch-back process. The high work function layer 107 may be formed by an etch-back process of a work function adjusting layer 107A, The first gate electrode 108 may be formed by an etch-back process of the first gate electrode layer 108A. According to another embodiment, the recessing process may include performing a planarization process first to expose the top surface of the hard mask 104 followed by an etch-back process. The top surface of the high work function layer 107 and the first gate electrode 108 may be at the same level.

Referring to FIG. 3D, the second gate electrode 109 may be formed over the first gate electrode 108. The second gate electrode 109 may include the same metal nitride as that of the first gate electrode 108. For example, the second gate electrode 109 may include titanium nitride (TM). The second gate electrode 109 may be formed through a series of processes of forming a second gate electrode layer over the high work function layer 107 and the first gate electrode 108 and then recessing the second gate electrode layer. The top surface of the second gate electrode 109 may be positioned at a level lower than the top surface of the substrate 101.

Referring to FIG. 3E, an ion implantation barrier layer 110 may be formed on the sidewall of the gate dielectric layer 106 which is exposed over the second gate electrode 109. The ion implantation barrier layer 110 may prevent the gate dielectric layer 106 or the like from being unnecessarily doped or diffused with impurities during a doping process. The ion implantation barrier layer 110 may include an easily removable material. For example, the ion implantation barrier layer 110 may include a polysilicon. In another embodiment, the ion implantation barrier layer 110 may include a dielectric material. For example, the ion implantation barrier layer 110 may include a silicon nitride.

According to another embodiment of the present invention, the ion implantation barrier layer 110 may be omitted.

Subsequently, a low work function adjusting element may be doped (IMP) onto a portion of the thickness of the second gate electrode 109 to form the third gate electrode 111 which includes the low work function adjusting element. The low work function adjusting element may be, for example, phosphorus (P) or lanthanum (La). Therefore, the third gate electrode 111 may include titanium nitride which is doped with phosphorus (P) (P-doped TiN) or titanium nitride which is doped with lanthanum (La) (La-doped TiN). The third gate electrode 111 has a lower work function than that of the first and second gate electrodes 108 and 109.

Subsequently, the ion implantation barrier layer 110 may be removed. In another embodiment, when the ion implantation barrier layer 110 is silicon nitride, the ion implantation barrier layer 110 may not be removed. In this case, a subsequent process may be performed over the ion implantation barrier layer 110.

Referring to FIG. 3F, a capping layer 112 may be formed over the third gate electrode 111. The capping layer 112 may include a dielectric material. The capping layer 112 may include silicon nitride. The capping layer 112 may have an ONO structure (Oxide-Nitride-Oxide). Subsequently, the capping layer 112 may be planarized to expose the top surface of the hard mask layer 104 while the capping layer 112 filling the gate trench 105 remains in the gate trench 105.

A buried gate structure 100G may be formed through a series of processes, which are described above. The buried gate structure 100G may include the gate dielectric layer 106, a gate electrode structure GE, and the capping layer 112.

Subsequently, an impurity doping process may be performed by an implantation or another doping technique to form a first source/drain region 113 and a second source/drain region 114 in the substrate 101. The first source/drain region 113 and the second source/drain region 114 may horizontally overlap with part or all of the third gate electrode 111. The first and second gate electrodes 108 and 109 may not horizontally overlap with the first and second source/drain regions 113 and 114.

As the first and second doped regions 113 and 114 are formed, a channel may be defined along the profile of the gate trench 105.

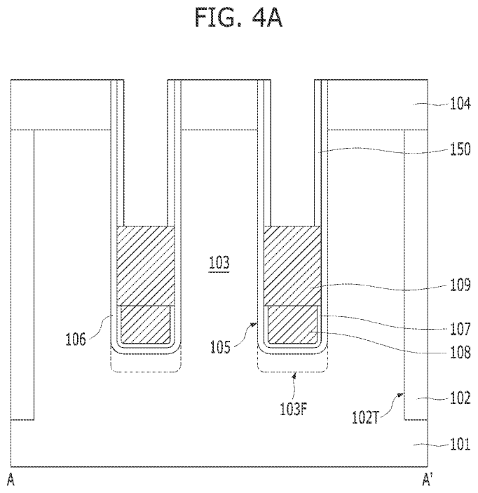

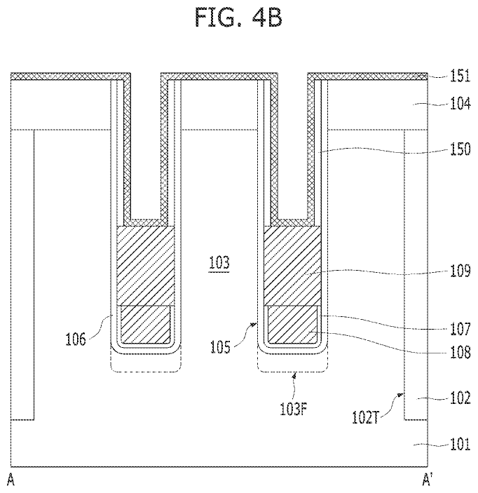

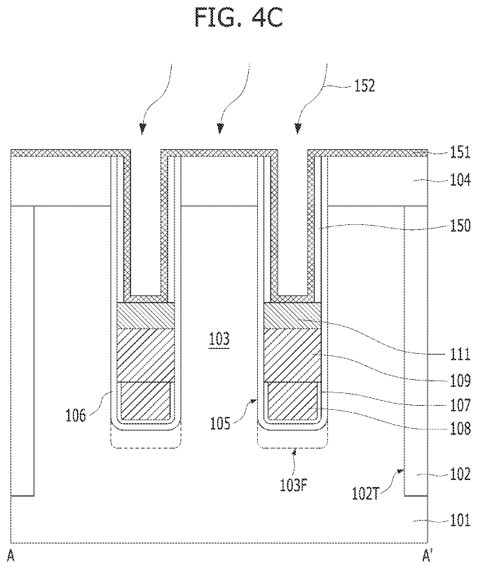

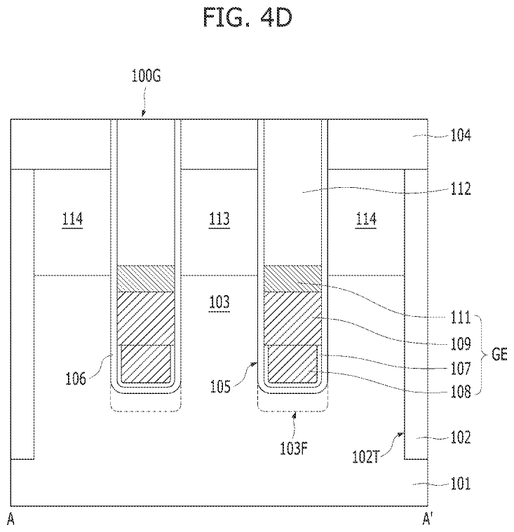

FIGS. 4A to 4D are cross-sectional views illustrating a method for fabricating the semiconductor device in accordance with the first embodiment of the present invention.

First, using the method described in reference to FIGS. 3A to 3D, the gate dielectric layer 106, the high work function layer 107, the first gate electrode 108, and the second gate electrode 109 may be formed in the gate trench 105.

Next, referring to FIG. 4A, a buffer spacer 150 may be formed on the sidewall of the gate dielectric layer 106 which is exposed over the second gate electrode 109, The buffer spacer 150 may include a dielectric material. For example, the buffer spacer 150 may include a silicon nitride. The buffer spacer 150 may be formed through a series of processes of conformally forming a dielectric material along the entire surface including the top surface of the second gate electrode 109 and then performing an etching process to expose the top surface of the second gate electrode 109.

Referring to FIG. 4B, a work function adjusting sacrificial layer 151 may be formed along the entire surface including the second gate electrode 109. The work function adjusting sacrificial layer 151 may include a material layer including a work function adjusting element. For example, the work function adjusting element may be phosphorus (P) or lanthanum (La). The work function adjusting sacrificial layer 151 may be or include a material layer containing PSG (Phosphorus Silicate Glass) or lanthanum.

Referring to FIG. 4C, a heat treatment 152 may be performed, during which the work function adjusting element in the work function adjusting sacrificial layer 151 is not diffused into the gate dielectric layer 106 or unnecessarily diffused due to the buffer spacer 150, but is diffused into the second gate electrode 109.

The work function adjusting element in the work function adjusting sacrificial layer 151 may be diffused into the second gate electrode 109 by the heat treatment 152. Accordingly, a predetermined thickness of the second gate electrode 109 may be replaced by the third gate electrode 111 into which the work function adjusting element is diffused. For example, the third gate electrode 111 may be phosphorus (P)-diffused titanium nitride (P-diffused TiN) or lanthanum (La)-diffused titanium nitride (La-diffused TiN).

Subsequently, the work function adjusting sacrificial layer 151 and the buffer spacer 150 may be removed. In another embodiment, when the buffer spacer 150 is silicon nitride, the buffer spacer 150 may not be removed. In this case, a subsequent process may be performed over the buffer spacer 150.

Referring to FIG. 4D, a capping layer 112 may be formed over the third gate electrode 111. The capping layer 112 may include a dielectric material. The capping layer 112 may include silicon nitride. The capping layer 112 may have an Oxide-Nitride-Oxide (ONO) structure. Subsequently, the capping layer 112 may be planarized in such a manner that the top surface of the hard mask layer 104 may be exposed. As a result, the capping layer 112 filling the gate trench 105 may remain.

A buried gate structure 100G may be formed by a series of processes, which are described above. The buried gate structure 100G may include the gate dielectric layer 106, a gate electrode structure GE, and the capping layer 112.

Subsequently, an impurity doping process may be performed by implantation or other doping technique. Accordingly, a first source/drain region 113 and a second source/drain region 114 may be formed in the substrate 101. The first source/drain region 113 and the second source/drain region 114 may horizontally overlap with part or all of the third gate electrode 111. The first and second gate electrodes 108 and 109 may not horizontally overlap with the first and second source/drain regions 113 and 114.

As the first and second doped regions 113 and 114 are formed, a channel may be defined along the surface of the gate trench 105.

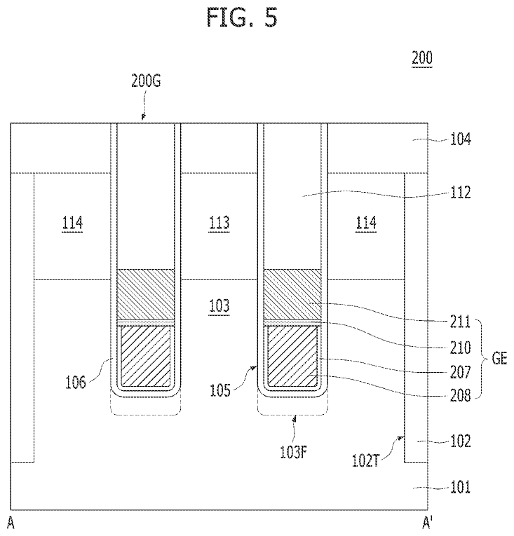

FIG. 5 is a cross-sectional view illustrating a semiconductor device in accordance with a second embodiment of the present invention. Description of some structures of the semiconductor device illustrated in FIG. 5 which are the same to those of the semiconductor device 100 shown in FIG. 2A will be omitted or will be described only briefly.

Referring to FIG. 5, the semiconductor device 200 may include a buried gate structure 200G, a first source/drain region 113, and a second source/drain region 114. An isolation layer 102 and an active region 103 may be formed over the substrate 101. The first source/drain region 113 and the second source/drain region 114 may be formed in the active region 103. A gate trench 105 crossing the active region 103 and the isolation layer 102 may be formed. A buried gate structure 200G may be formed in the gate trench 105. A channel may be formed between the first source/drain region 113 and the second source/drain region 114 by the buried gate structure 200G. The channel may be defined along the profile of the gate trench 105. The semiconductor device 200 may be a portion of a memory cell. For example, the semiconductor device 200 may be a cell transistor of a DRAM.

A buried gate structure 200G may be embedded in the gate trench 105. The buried gate structure 200G may be positioned in the active region 103 between the first source/drain region 113 and the second source/drain region 114 and may extend into the isolation layer 102. In the buried gate structure 200G, the bottom surface of a portion positioned in the active region 103 and the bottom surface of a portion positioned in the isolation layer 102 may be positioned at different levels. When the fin 103F is omitted, in the buried gate structure 200G, the bottom surface of the portion positioned in the active region 103 and the bottom surface of the portion positioned in the isolation layer 102 may be positioned at the same level.

The buried gate structure 200G may include a gate dielectric layer 106, a gate electrode structure GE, and a capping layer 112.

The top surface of the gate electrode structure GE may be positioned at a lower level than the top surface of the active region 103. The gate electrode structure GE may include a stacked structure of a high work function layer 207, a first gate electrode 208, a diffusion barrier layer 210, and a second gate electrode 211.

The high work function layer 207 may have a relatively high work function. Here, the high work function refers to a work function which is higher than the mid-gap work function of silicon. The low work function refers to a work function that is lower than the mid-gap work function of silicon. For example, the high work function is higher than approximately 4.5 eV, and the low work function is lower than approximately 4.5 eV.

The high work function layer 207 may include at least one of a metal oxide or a metal nitride. The high work function layer 207 may include at least one of titanium oxide (TiO₂), aluminum oxide (Al₂O₃), and titanium aluminum nitride (TiAlN). A threshold voltage Vt may be modulated by the high work function layer 207. For example, the threshold voltage Vt may be shifted by the high work function layer 207.

The first gate electrode 208 may include a metal nitride. For example, the first gate electrode 208 may include titanium nitride (TiN).

The diffusion barrier layer 210 may be or include a material having a higher density than the film qualities of the first gate electrode 208 and the second gate electrode 211. The diffusion barrier layer 210 may serve to prevent the diffusion of a dopant into the first gate electrode 208 during a doping process for adjusting the work function of the second gate electrode 211. The diffusion barrier layer 210 may include a dielectric material. For example, the diffusion barrier layer 210 may include silicon nitride or silicon oxide. The diffusion barrier layer 210 may be formed to have a thickness that allows the first gate electrode 208 and the second gate electrode 211 to conduct each other. For example, the diffusion barrier layer 210 may be formed to a thickness of less than 50 Å.

The second gate electrode 211 may include the same metal nitride as that of the first gate electrode 208. The second gate electrode 211 may include a metal nitride which is doped with a low work function adjusting element. The second gate electrode 211 may have a lower work function than that of the first gate electrode 208.

For example, the low work function adjusting element may be phosphorus (P) or lanthanum (La). For example, the second gate electrode 211 may include titanium nitride which is doped/diffused with phosphorus (P) (P-doped/diffused TiN) or titanium nitride which is doped/diffused with lanthanum (La) (La-doped/diffused TiN).

The first gate electrode 208 is also referred to as a ‘lower gate electrode’. The second gate electrode 211 is also referred to as an ‘upper gate electrode’, The lower gate electrode and the upper gate electrode may have different work functions. The upper gate electrode may have a lower work function than that of the lower gate electrode. The top surface of the lower gate electrode may be positioned at a lower level than the bottom surfaces of the first and second source/drain regions 113 and 114. The lower gate electrode may not horizontally overlap with the first and second source/drain regions 113 and 114. The bottom surface of the upper gate electrode may be positioned at a lower level than the bottom surfaces of the first and second source/drain regions 113 and 114, The upper gate electrode may horizontally overlap with the first and second source/drain regions 113 and 114. In an embodiment, the thickness of the lower gate electrode may be greater than that of the upper gate electrode, however, the concept and spirit of the present embodiment may not be limited thereto. In another embodiment, the thickness of the lower gate electrode may be formed the same as the thickness of the upper gate electrode or may be thinner than the thickness of the upper gate electrode.

The capping layer 112 may protect the third gate electrode 211. The capping layer 112 may include a dielectric material. The capping layer 112 may include silicon nitride, silicon oxynitride, or a combination thereof. According to another embodiment of the present invention, the capping layer 112 may include a combination of silicon nitride and silicon oxide. The capping layer 112 may include a silicon nitride liner and a Spin-On Dielectric (SOD) material.

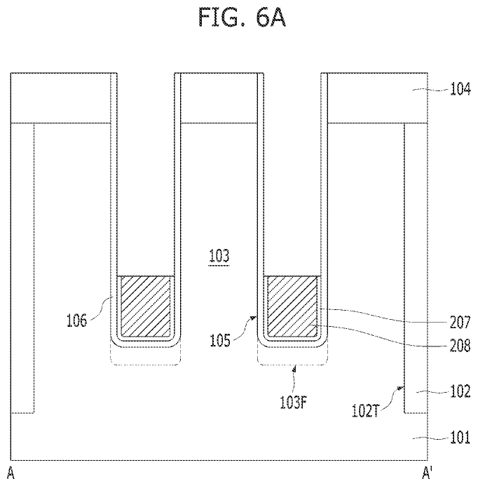

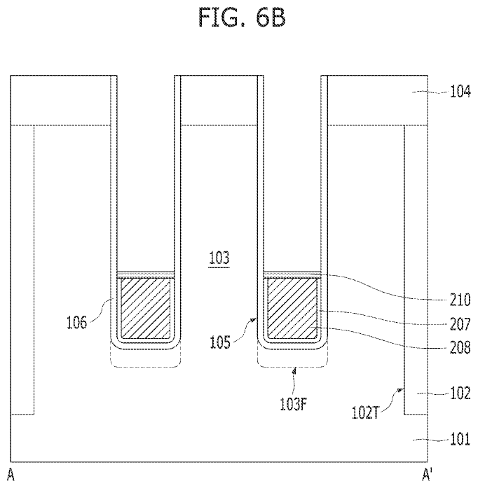

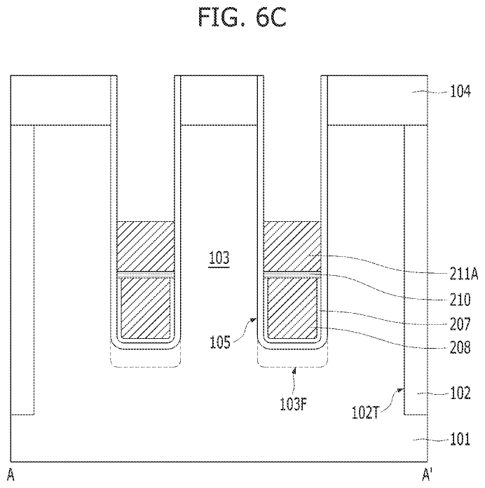

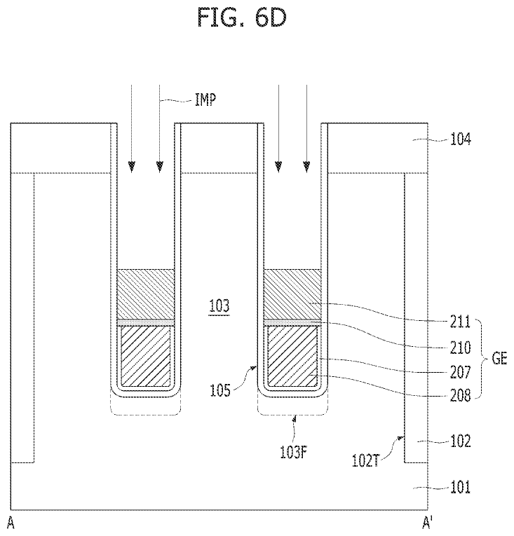

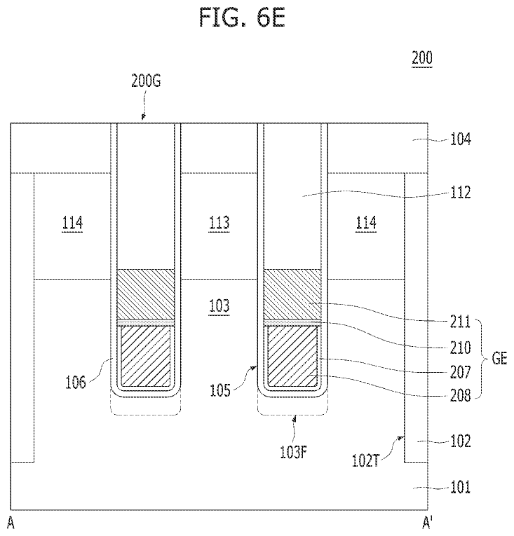

FIGS. 6A to 6E are cross-sectional views illustrating a method for fabricating the semiconductor device in accordance with the second embodiment of the present invention.

First, the gate dielectric layer 106 may be formed in the gate trench 105 by the method illustrated in FIGS. 3A and 3B.

Next, referring to FIG. 6A, the high work function layer 207 and the first gate electrode 208 filling the bottom portion of the gate trench 105 may be formed. The top surfaces of the high work function layer 207 and the first gate electrode 208 may be positioned at the same level. A recessing process may be performed to form the high work function layer 207 and the first gate electrode 208, The recessing process may be performed by dry etching, for example, an etch-back process. The high work function layer 207 may be formed by an etch-back process of the work function adjusting layer 107A (refer to FIG. 3B). The first gate electrode 208 may be formed by an etch-back process of the first gate electrode layer 108A (refer to FIG. 3B). According to another embodiment of the present invention, the recessing process may be performed by performing a planarization process first in such a manner that the top surface of the hard mask 104 is exposed, and then performing an etch-back process subsequently. The top surfaces of the high work function layer 207 and the first gate electrode 208 may be positioned at the same level.

Referring to FIG. 6B, a diffusion barrier layer 210 may be formed over the first gate electrode 208.

The diffusion barrier layer 210 may be or include a material having a higher density than the film qualities of the first gate electrode 208 and the second gate electrode 211. The diffusion barrier layer 210 may serve to prevent dopant diffusion into the first gate electrode 208 during a doping process for adjusting the work function of the second gate electrode 211. The diffusion barrier layer 210 may be formed to have a thickness that allows the first gate electrode 208 and the second gate electrode 211 to conduct each other.

Referring to FIG. 6C, a metal nitride 211A may be formed over the diffusion barrier layer 210. The metal nitride 211A may include a metal nitride which is the same as that of the first gate electrode 208, For example, the metal nitride 211A may include titanium nitride (TiN). The metal nitride 211A may be formed through a series of processes of forming a metal nitride layer over the high work function layer 207 and the first gate electrode 208 and recessing the metal nitride layer. The top surface of the metal nitride 211A may be positioned at a level lower than the top surface of the substrate 101.

Referring to FIG. 6D, a second gate electrode 211 may be formed by doping the metal nitride 211A (refer to FIG. 6C) with a low work function adjusting element through a doping process, which is IMP.

For example, the low work function adjusting element may be phosphorus (P) or lanthanum (La), Accordingly, the second gate electrode 211 may include titanium nitride which is doped with phosphorus (P) (P-doped TiN) or titanium nitride which is doped with lanthanum (La) (La-doped TiN). The second gate electrode 211 may have a lower work function than that of the first gate electrode 208, The thickness of the second gate electrode 211 may be thinner than the thickness of the first gate electrode 208, but the concept and spirit of the present embodiment may not be limited thereto, According to another embodiment of the present invention, the thickness of the second gate electrode 211 may be the same as the thickness of the first gate electrode 208 or may be greater than the thickness of the first gate electrode 208.

According to another embodiment of the present invention, an ion implantation barrier layer 110 is formed on the sidewall of the gate dielectric layer 106 as illustrated in FIG. 3E, before the doping process (IMP) is performed.

According to another embodiment of the present invention, the low work function adjusting element may be diffused into the second gate electrode 211 through the diffusion process illustrated in FIGS. 4B and 4C. Accordingly, the second gate electrode 211 may be phosphorus (P)-diffused titanium nitride (P-diffused TiN) or lanthanum (La)-diffused titanium nitride (La-diffused TiN).

Referring to FIG. 6E, a capping layer 112 is formed over the second gate electrode 211. The capping layer 112 may include a dielectric material. The capping layer 112 may include silicon nitride. The capping layer 112 may have an Oxide-Nitride-Oxide (ONO) structure. Subsequently, the capping layer 112 may be planarized in such a manner that the top surface of the hard mask layer 104 may be exposed. Accordingly, the capping layer 112 filling the gate trench 105 may remain.

A buried gate structure 200G is formed by a series of processes, which are described above. The buried gate structure 200G may include the gate dielectric layer 106, a gate electrode structure GE, and the capping layer 112.

Subsequently, an impurity doping process is performed by an implantation or another doping technique. As a result, a first source/drain region 113 and a second source/drain region 114 are formed in the substrate 101. The first source/drain region 113 and the second source/drain region 114 overlap horizontally with part or all of the second gate electrode 211, The first gate electrode 208 do not overlap horizontally with the first and second source/drain regions 113 and 114.

As the first and second doped regions 113 and 114 are formed, a channel (not shown) may be defined along the surface of the gate trench 105.

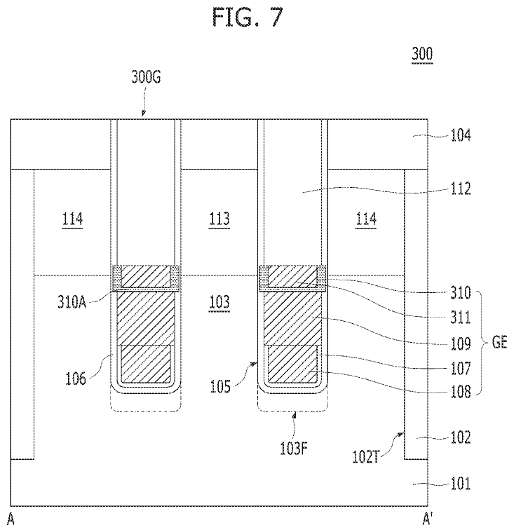

FIG. 7 is a cross-sectional view illustrating a semiconductor device 300 in accordance with a third embodiment of the present invention. Some structures of the semiconductor device 300 illustrated in FIG. 7 may be the same as those of the semiconductor device 100 shown in FIG. 2A. For the sake of convenience of description, the same reference numerals may be omitted or may be briefly described.

Referring to FIG. 7, the semiconductor device 300 may include a buried gate structure 300G, a first source/drain region 113, and a second source/drain region 114, An isolation layer 102 and an active region 103 are formed in the substrate 101, The first source/drain region 113 and the second source/drain region 114 are formed in the active region 103, A trench crossing the active region 103 and the isolation layer 102, which is a gate trench 105, is formed. A buried gate structure 300G is formed in the gate trench 105. A channel (not shown) is formed between the first source/drain region 113 and the second source/drain region 114 by the buried gate structure 300G. The channel may be defined along the profile of the gate trench 105. The semiconductor device 300 may be a portion of a memory cell. For example, the semiconductor device 300 may be a cell transistor of a DRAM.

A buried gate structure 300G may be embedded in the gate trench 105. The buried gate structure 300G may extend into the isolation layer 102 while being positioned in the active region 103 between the first source/drain region 113 and the second source/drain region 114. In the buried gate structure 300G, the bottom surface of a portion positioned in the active region 103 and the bottom surface of a portion positioned in the isolation layer 102 are positioned at different levels. When the fin 103F is omitted, in the buried gate structure 300G, the bottom surface of the portion positioned in the active region 103 and the bottom surface of the portion positioned in the isolation layer 102 are positioned at the same level.

The buried gate structure 300G may include the gate dielectric layer 106, a gate electrode structure GE, and the capping layer 112.

The top surface of the gate electrode structure GE is positioned at a lower level than the top surface of the active region 103. The gate electrode structure GE may include a stacked structure of a high work function layer 107, a first gate electrode 108, a second gate electrode 109, a low work function layer 310, and a third gate electrode 311.

The high work function layer 107 may have a relatively high work function. Herein, the high work function refers to a work function which is higher than the mid-gap work function of silicon. The low work function refers to a lower work function than the mid-gap work function of silicon. For example, the high work function has a work function which is higher than approximately 4.5 eV, and the low work function has a lower work function than approximately 4.5 eV.

The high work function layer 107 may include at least one of a metal oxide or a metal nitride. The high work function layer 107 may include at least one of titanium oxide (TiO₂), aluminum oxide (Al₂O₃), and titanium aluminum nitride (TiAlN). A threshold voltage Vt may be modulated by the high work function layer 107. For example, the threshold voltage Vt may be shifted by the high work function layer 107.

The first to third gate electrodes 108, 109, and 311 may include the same material. The first to third gate electrodes 108, 109, and 311 may include a metal nitride. For example, the first to third gate electrodes 108, 109, and 311 may include titanium nitride (TiN).

A low work function layer 310 is positioned between the third gate electrode 311 and the gate dielectric layer 106. A low work function inducing layer 310A is positioned between the second gate electrode 109 and the third gate electrode 311, The low work function inducing layer 310A and the low work function layer 310 may be continuous. The low work function layer 310 may be a reactant of the low work function inducing layer 310A and the gate dielectric layer 106, The thickness of the low work function layer 310 may be greater than the thickness of the low work function inducing layer 310A.

The low work function inducing layer 310A may be a metal oxide containing a low work function adjusting element. For example, the low work function adjusting element may include lanthanum (La). For example, the low work function inducing layer 310A may be lanthanum oxide (La₂O₃). The low work function layer 310 may be a reactant that is formed as the low work function adjusting element in the low work function inducing layer 310A is diffused into the gate dielectric layer 106. For example, the low work function layer 310 may include lanthanum-diffused silicon oxide (La-diffused SiO₂). For example, the low work function layer 310 is also referred to as ‘lanthanum silicate’.

The capping layer 112 may serve to protect the third gate electrode 311. The capping layer 112 may include a dielectric material. The capping layer 112 may include silicon nitride, silicon oxynitride, or a combination thereof, According to another embodiment of the present invention, the capping layer 112 may include a combination of silicon nitride and silicon oxide. The capping layer 112 may include a silicon nitride liner and a Spin-On-Dielectric (SOD) material.

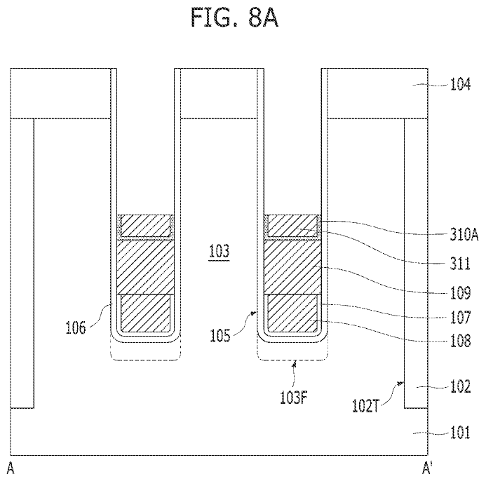

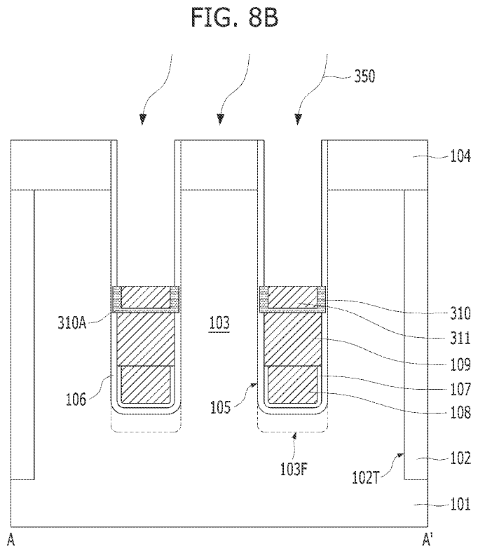

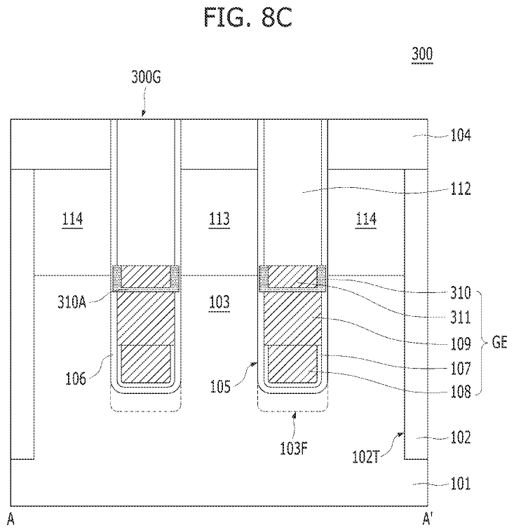

FIGS. 8A to 8C are cross-sectional views illustrating a method for fabricating the semiconductor device in accordance with the third second embodiment of the present invention.

First, the gate dielectric layer 106, a high work function layer 107, a first gate electrode 108, and a second gate electrode 109 may be formed in a gate trench 105 by the method illustrated in FIGS. 3A to 3D.

Next, referring to FIG. 8A, a low work function inducing layer 310A and a third gate electrode 311 filling a portion of the gate trench 105 may be formed over the second gate electrode 109.

The low work function inducing layer 310A and the third gate electrode 311 may be formed through a series of processes of conformally forming the low work function inducing layer 310A along the entire surface including the second gate electrode 109, forming a third gate electrode layer (not shown) that gap-fills the gate trench 105 over the low work function inducing layer 310A, and then recessing the low work function inducing layer 310A and the third gate electrode layer.

The low work function inducing layer 310A may cover the top surface of the second gate electrode 109 and a portion of a sidewall of the gate dielectric layer 106. The low work function inducing layer 310A may be a metal oxide containing a low work function adjusting element. For example, the low work function adjusting element may include lanthanum (La). For example, the low work function inducing layer 310A may be lanthanum oxide (La₂O₃).

The third gate electrode 311 may include the same metal nitride as those of the first and second gate electrodes 108 and 109. For example, the third gate electrode 311 may include titanium nitride (TiN).

Referring to FIG. 8B, a low work function layer 310 may be formed between the sidewall of the third gate electrode 311 and the gate dielectric layer 106 through a heat treatment process 350.

The low work function layer 310 may be a reactant of the low work function inducing layer 310A and the gate dielectric layer 106, The low work function layer 310 may be a reactant which is formed as the low work function adjusting element in the low work function inducing layer 310A is diffused into the gate dielectric layer 106 because of the heat treatment process 350. For example, the low work function layer 310 may Include lanthanum-diffused silicon oxide (La-diffused SiO₂), The low work function layer 310 is referred to also as ‘lanthanum silicate’.

Since the low work function inducing layer 310A between the third gate electrode 311 and the second gate electrode 109 is not in contact with the gate dielectric layer 106, it may remain as it is.

Referring to FIG. 8C, a capping layer 112 may be formed over the third gate electrode 311. The capping layer 112 may include a dielectric material. The capping layer 112 may include silicon nitride. The capping layer 112 may have an Oxide-Nitride-Oxide (ONO) structure, Subsequently, the capping layer 112 may be planarized in such a manner that the top surface of the hard mask layer 104 is exposed. As a result, the capping layer 112 filling the gate trench 105 may remain.

A buried gate structure 300G may be formed by a series of processes, which are described above. The buried gate structure 300G may include the gate dielectric layer 106, a gate electrode structure GE, and the capping layer 112.

Subsequently, an impurity doping process may be performed by an implantation or another doping technique. As a result, a first source/drain region 113 and a second source/drain region 114 may be formed in the substrate 101. The first source/drain region 113 and the second source/drain region 114 may horizontally overlap with part or all of the third gate electrode 311. The first gate electrode 208 may not horizontally overlap with the first and second source/drain regions 113 and 114.

As the first and second doped regions 113 and 114 are formed, a channel may be defined along the surface of the gate trench 105.

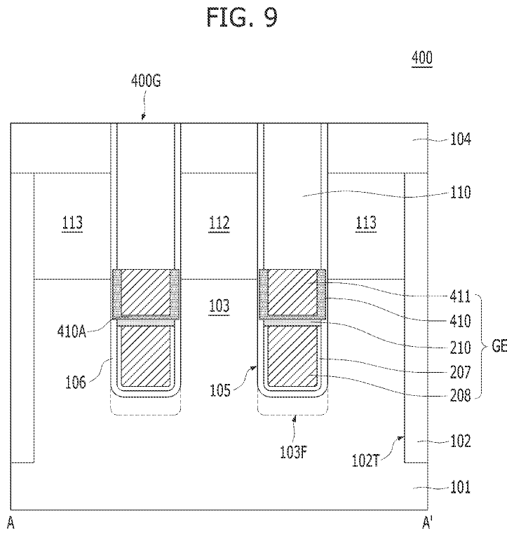

FIG. 9 is a cross-sectional view illustrating a semiconductor device in accordance with a fourth embodiment of the present invention embodiment. Some structures of the semiconductor device shown in FIG. 9 may be the same as those of the semiconductor device 200 shown in FIG. 5. For convenience of description, the same reference numerals will be omitted or will be briefly described.

Referring to FIG. 9, the semiconductor device 400 may include a buried gate structure 400G, a first source/drain region 113, and a second source/drain region 114. An isolation layer 102 and an active region 103 may be formed over the substrate 101. The first source/drain region 113 and the second source/drain region 114 may be formed in the active region 103. A trench crossing the active region 103 and the isolation layer 102, that is, the gate trench 105, may be formed. A buried gate structure 200G may be formed in the gate trench 105. A channel may be formed between the first source/drain region 113 and the second source/drain region 114 by the buried gate structure 400G. The channel may be defined along the profile of the gate trench 105. The semiconductor device 400 may be a portion of a memory cell. For example, the semiconductor device 400 may be a cell transistor of a DRAM.

The buried gate structure 400G may be embedded in the gate trench 105. The buried gate structure 400G may be positioned in the active region 103 between the first source/drain region 113 and the second source/drain region 114 and may extend into the isolation layer 102. In the buried gate structure 400G, the bottom surface of a portion positioned in the active region 103 and the bottom surface of a portion positioned in the isolation layer 102 may be positioned at different levels. When the fin 103F is omitted, in the buried gate structure 400G, the bottom surface of the portion positioned in the active region 103 and the bottom surface of the portion positioned in the isolation layer 102 may be positioned at the same level.

The buried gate structure 400G may include the gate dielectric layer 106, a gate electrode structure GE, and the capping layer 112.

The top surface of the gate electrode structure GE may be positioned at a lower level than the top surface of the active region 103. The gate electrode structure GE may include a stacked structure of a high work function layer 207, a first gate electrode 208, a diffusion barrier layer 210, a low work function layer 410, and a second gate electrode 411.

The high work function layer 207 may have a relatively high work function, Herein, the high work function refers to a work function which is higher than the mid-gap work function of silicon. The low work function refers to a work function that is lower than the mid-gap work function of silicon. For example, the high work function has a work function which is higher than approximately 4.5 eV, and the low work function has a lower work function than approximately 4.5 eV.

The high work function layer 207 may include at least one of a metal oxide or a metal nitride. The high work function layer 207 may include at least one of titanium oxide (TiO₂), aluminum oxide (Al₂O₃), and titanium aluminum nitride (TiAlN). A threshold voltage Vt may be modulated by the high work function layer 207. For example, the threshold voltage may be shifted by the high work function layer 207.

The first gate electrode 208 may include a metal nitride. For example, the first gate electrode 208 may include titanium nitride (TiN).

The diffusion barrier layer 210 may be or include a material having a higher density than the film qualities of the first gate electrode 208 and the second gate electrode 411. The diffusion barrier layer 210 may serve to prevent the low work function adjusting element in the low work function inducing layer 410A from being diffused into the first gate electrode 208. The diffusion barrier layer 210 may be formed to have a thickness that allows the first gate electrode 208 and the second gate electrode 211 to conduct each other.

The second gate electrode 411 may include a metal nitride which is the same as that of the first gate electrode 208. For example, the second gate electrode 411 may include titanium nitride.

A low work function layer 410 may be positioned between the second gate electrode 411 and the gate dielectric layer 106, The low work function inducing layer 410A may be positioned between the diffusion barrier layer 210 and the second gate electrode 411. The low work function inducing layer 410A and the low work function layer 410 may be continuous. The low work function layer 410 may be a reactant of the low work function inducing layer 410A and the gate dielectric layer 106. The thickness of the low work function layer 410 may be greater than the thickness of the low work function inducing layer 410A.

The low work function inducing layer 410A may be a metal oxide containing a low work function adjusting element. For example, the low work function adjusting element may include lanthanum (La). For example, the low work function inducing layer 410A may be lanthanum oxide (La₂O₃). The low work function layer 410 may be a reactant which is formed as the low work function adjusting element in the low work function inducing layer 410A is diffused into the gate dielectric layer 106. For example, the low work function layer 410 may include lanthanum-diffused silicon oxide (La-diffused SiO₂). For example, the low work function layer 410 is referred to also as ‘lanthanum silicate’.

The capping layer 112 may serve to protect the second gate electrode 411. The capping layer 112 may include a dielectric material. The capping layer 112 may include silicon nitride, silicon oxynitride, or a combination thereof, According to another embodiment of the present invention, the capping layer 112 may include a combination of silicon nitride and silicon oxide. The capping layer 112 may include a silicon nitride liner and a spin on dielectric (SOD) material.

According to an embodiment of the present invention, gate-induced drain leakage (GIRL) may be reduced by applying a high work function layer between a buried gate electrode and a channel and forming a gate electrode overlapping with a source/drain region as a low work function layer.

While the present invention has been described with respect to specific embodiments, it will be apparent to those skilled in the art, after having read the present disclosure, that various changes and modifications may be made without departing from the spirit and scope of the invention as defined in the following claims.

What is claimed is:

1. A semiconductor device comprising:
a substrate including a gate trench;
a gate dielectric layer formed along sidewalls and bottom surfaces of the gate trench;
a high work function layer and a lower gate electrode that fill a bottom portion of the gate trench over the gate dielectric layer;
an upper gate electrode including a low work function adjusting element over the lower gate electrode and including the same metal nitride as a material of the lower gate electrode; and
a capping layer that gap-fills the other portion of the gate trench over the upper gate electrode.

2. The semiconductor device of claim 1, wherein the high work function layer is conformally formed over the gate dielectric layer.

3. The semiconductor device of claim 1, wherein the high work function layer includes a metal oxide or metal nitride.

4. The semiconductor device of claim 1, wherein the high work function layer includes at least one of titanium oxide, aluminum oxide, and titanium aluminum nitride.

5. The semiconductor device of claim 1, wherein the lower gate electrode includes titanium nitride.

6. The semiconductor device of claim 1, wherein the low work function adjusting element includes phosphorus (P) or lanthanum (La).

7. The semiconductor device of claim 1, further comprising:
a diffusion barrier layer between the lower gate electrode and the upper gate electrode.

8. The semiconductor device of claim 1, further comprising:
source/drain regions formed in the substrate on both sides of the gate trench.

9. The semiconductor device of claim 8, wherein a top surface of the lower gate electrode is positioned at a lower level than a bottom surface of the source/drain regions.

10. The semiconductor device of claim 8, wherein the source/drain regions horizontally overlap with part or all of the upper gate electrode.

11. A semiconductor device comprising:
a substrate including a gate trench;
a gate dielectric layer formed along sidewalls and a bottom surface of the gate trench;
a high work function layer and a lower gate electrode that fill a bottom portion of the gate trench over the gate dielectric layer;
a low work function layer and an upper gate electrode that fill a portion of the gate trench over the lower gate electrode; and
a capping layer that gap-fills the other portion of the gate trench over the upper gate electrode and the low work function layer.

12. The semiconductor device of claim 11, further comprising a low work function inducing layer is positioned between the lower gate electrode and the upper gate electrode.

13. The semiconductor device of claim 12, wherein the low work function inducing layer and the low work function layer are continuous.

14. The semiconductor device of claim 12, wherein the low work function layer includes a reactant of lanthanum oxide and the gate dielectric layer.

15. The semiconductor device of claim 11, wherein the low work function layer includes lanthanum silicate.

16. The semiconductor device of claim 11, wherein the low work function layer includes lanthanum-diffused silicon oxide (La-diffused SiO₂).

17. The semiconductor device of claim 12, wherein the low work function inducing layer is lanthanum oxide (La₂O₃).

18. The semiconductor device of claim 11, further comprising:
a diffusion barrier layer formed between the lower gate electrode and the upper gate electrode.

19. The semiconductor device of claim 12, further comprising:
source/drain regions formed in the substrate on both sides of the gate trench.

20. A method for fabricating a semiconductor device, the method comprising:
forming a gate trench in a substrate;
forming a gate dielectric layer along sidewalls and a bottom surface of the gate trench;
forming a high work function layer and a lower gate electrode that fill a bottom portion of the gate trench over the gate dielectric layer;
forming an upper gate electrode including a low work function adjusting element over the lower gate electrode and including the same metal material as a material of the lower gate electrode; and
forming a capping layer gap-filling the other portion of the gate trench over the upper gate electrode.

21. The method of claim 20, wherein the forming of the high work function layer and the lower gate electrode that fill the bottom portion of the gate trench over the gate dielectric layer includes:
forming a work function adjusting layer conformally over the gate dielectric layer;
forming a lower gate electrode layer over the work function adjusting layer to gap-fill the gate trench; and
recessing the work function adjusting layer and the lower gate electrode layer.

22. The method of claim 20, wherein the high work function layer includes a metal oxide or a metal nitride.

23. The method of claim 20, wherein the high work function layer includes at least one of titanium oxide, aluminum oxide, and titanium aluminum nitride.

24. The method of claim 20, wherein the lower gate electrode includes titanium nitride.

25. The method of claim 20, wherein the low work function adjusting element includes phosphorus (P) or lanthanum (La).

26. The method of claim 20, wherein the forming of the upper gate electrode includes:
forming a metal nitride which is the same as a material of the lower gate electrode over the lower gate electrode;
forming an ion implantation barrier layer which exposes a top surface of the metal nitride on a sidewall of the gate dielectric layer;
doping the metal nitride with a low work function adjusting element; and
removing the ion implantation barrier layer.

27. The method of claim 20, wherein the forming of the upper gate electrode includes:
forming a metal nitride which is the same as a material of the lower gate electrode over the lower gate electrode;
forming a buffer spacer which exposes a top surface of the metal nitride on a sidewall of the gate dielectric layer;
forming a work function adjusting sacrificial layer conformally on a profile including a top surface of the metal nitride;
diffusing a work function adjusting element into the metal nitride through a heat treatment process; and
removing the work function adjusting sacrificial layer and the buffer spacer.

28. The method of claim 20, further comprising:
forming a diffusion barrier layer over the lower gate electrode, before the forming of the upper gate electrode.

29. The method of claim 20, further comprising:
forming source/drain regions in the substrate on both sides of the gate trench, after the forming of the capping layer.

30. A method for fabricating a semiconductor device, the method comprising:
forming a gate trench in a substrate;
forming a gate dielectric layer along sidewalls and a bottom surface of the gate trench;
forming a high work function layer and a lower gate electrode that fill a bottom portion of the gate trench over the gate dielectric layer;
forming a low work function layer and an upper gate electrode that fill a portion of the gate trench over the lower gate electrode; and
forming a capping layer that gap-fills the other portion of the gate trench over the upper gate electrode.

31. The method of claim 30, wherein the forming of the low work function layer and the upper gate electrode includes:
forming a low work function inducing layer along a surface of the gate trench over the lower gate electrode;
forming a metal nitride which is the same as a material of the lower gate electrode over the low work function inducing layer;
recessing the low work function inducing layer and the metal nitride; and
forming a low work function layer by reacting the low work function inducing layer with a portion of the gate dielectric layer through a heat treatment process.

32. The method of claim 30, further comprising:
forming a diffusion barrier layer over the lower gate electrode, before the forming of the low work function layer and the upper gate electrode.
